(19) United States
(12) Patent Application Publication
(10) Pub. No.: US 2004/0045497 A1
(43) Pub. Date: Mar. 11, 2004

(54) Analysis method for detecting three-dimensional trace element distribution patterns and corresponding device for carrying out this method

(76) Inventors: Michael Kriews, Oering (DE); Erich Dunker, Otterndorf (DE); Heiko Reinhardt, Elmshorn (DE); Ingo Beninga, Bremen (DE); Erwin Hoffmann, Neuendorf (DE); Christian Luedke, Berlin (DE)

Correspondence Address: Law Offices of Karl Hormann, PO Box 381516, Cambridge, MA, 02238-1516, US

(21) Appl. No.: 10/250,736

(22) PCT Filed: Jan. 5, 2001
(86) PCT No.: PCT/DE01/00028

(51) Int. Cl. C30B 1/00

(52) U.S. Cl. 117/2

(57) ABSTRACT

During an inventive laser ablation ICP-MS analysis method, solid matter samples (39) are examined in a frozen initial state. To this end, the sample chamber (2) as well as the carrier gas stream (12), which transports the ablated sample particles into the plasma (ICP-MS), are cooled to low temperatures (Tₖ). The physical conservation, especially of ice samples (3), results in obtaining a particularly high local resolution since their annual layers often remain preserved. An advantageous device (1) is provided with an insulated chamber (2) that can be cooled and with a simple circulating cooling device (17). The laser ablation analysis method can be used for all freezable sample materials used in mass spectrometry.

The invention relates to an analytical method of detecting the spatial distribution patterns of trace elements in a solid matter sample by means of computer-assisted spatially resolved ablation of particulate sample material by laser beam bombardment in a sample chamber permeated by a stream of inert carrier gas and subsequent transfer of the ablated sample material, by means of the carrier gas stream, into an inductively coupled plasma as a source of ionization for recording data by a mass spectrometer, and to an apparatus for practicing the method.

Layers of ice and glaciers in polar regions develop by the continuous precipitation of snow. Aerosols of marine, terrigenous, anthropogenetic and cosmic origin deposit themselves on polar ice and snow. Thus, the huge snow and ice surfaces of the polar regions act as climate archives and provide invaluable information of up to 250,000 years of the history of the earth's climate. Changes caused by the environment can be detected as chemical and physical parameters in ice cores drilled out of ice layers and glaciers. Amongst the chemical parameters, trace elements are of particular interest, as from them it is possible to derive assumptions regarding unaffected environmental changes and environmental pollution by anthropogenous activity. Analytical techniques have been developed to prove the existence of such ultra traces in the available extremely limited ice core volumes. In this connection, high temporal and spatial resolution and the lowest possible contamination of the sample material during analysis are of particular importance.

The paper “Determination of the Trace Elements in a Mizuho Ice Core Sample by a Combination of Conventional and High Resolution Inductively Coupled Plasma Mass Spectrometry” by T. Shimamura et al. (Proc. NIPR Symp. Polar Meteorol. Glaciol., 9, 33-34, 1995) describes a method which made possible the detection of seventeen different trace elements in an ice core from Antarctica. The method is based upon atomic mass spectrometric analysis of the material to be examined with an inductively coupled plasma as an ion source (ICP-MS—Inductively Coupled Plasma—Mass Spectrometry). The analysis of the material sample ionized in the plasma may be conducted with a quadrupole mass spectrometer (Q-ICP-MS—quadrupole based) or with a mass spectrometer of higher resolution (HR-ICP-MS—High Resolution). Depending upon the resolution, various trace elements of different occurrences can be detected. During the analysis the ICP reaches a temperature of between 8,000° and 10,000° K and is cooled by a gas stream. The prepared sample is introduced into the hot plasma by a special nebulator. For such a method, the ice sample has to be incrementally melted from the exterior to the interior which leads to a significantly reduced spatial resolution. Furthermore, many interfering factors have to be taken into consideration, especially the contamination of the sample by contact with solvents and changing vessels during its preparation and during the analysis by the measuring device.

A very complex sample preparation intended to result in minimizing the problem of contamination, is known from the paper “Determination of Trace Elements in an Arctic Ice Core by ICP/MS with a Desolvated Micro-Concentric Nebulizer” by S. Matoba et al. (Journal of Environmental Chemistry, Vol. 8, No. 3, pp. 421-427, 1998). In it, an ice sample shaved off the surface, for preventing fissures, is initially incrementally heated to room temperature in a cooled clean room, is then washed with high-purity water in a clean room, and is thereafter melted in various Teflon® containers, in 50 g quantities, to prevent contamination. The remaining sample residue is frozen again. For the preparation of individual samples, for instance five of them, nitric acid is added to the melted sample. The nebulizer used in this example is a micro-concentric nebulizer (MCN) which offers advantages over conventional pneumatic nebulizers and ultra-sonic nebulizers.

A precondition of the mentioned processes of the described chemico-physical methods for analytical examination of elements in drilled ice cores is that the samples must first be melted by complex methods of preparation so that they may be sprayed into the plasma flame by the nebulizer. Because of the relative large volumes used in solvent analysis, the spatial and, hence, the temporal (annual layers) resolution of the detected trace elements in the ice sample are significantly reduced. In addition to its time-consuming preparation, it is, more particularly, the high risk of contamination in the prepared ice samples by their contact with different liquids, vessels and process equipment which constitutes a great disadvantage of the known methods, since contamination of a sample leads to a significant distortion of the results of a measurement.

From U.S. Pat. No. 4,920,264, there is known a method of preparing or treatment of large organic molecules to render them suitable for mass spectrometry. For this purpose, nonvolatile and thermally labile high molecular compounds are produced and frozen in a matrix of a low-molecular solvent. This prevents undesirable fragmentations and clusterings during desorption. The frozen state of the frozen solution is maintained in a vacuum chamber in dependence of its vapor pressure. Following their desorption in the vacuum chamber, the high molecular organic substances are photo-ionized or ionized by laser beam bombardment and fed to a mass spectrometer for organic analysis. When selecting the desorption and ionizing energy, care must be taken not to destroy the sensitive molecules. Thus, the described preparation and treatment method using a homogenous solution as a starter material is unsuited for subsequent detection of inorganic trace elements, which ionize only at very high temperatures, since the laser energy applied is insufficient. Spatial detection of trace elements for determining their qualitative and quantitative distribution pattern cannot be performed with the known method of U.S. Pat. No. 4,920,264.

The analytical method representing the closest state of the art (described, for instance, in the manual (1991 edition) of the “Laser-Zubehör Modell 320” [Laser Accessory Model 320] of the company Perkin-Elmer and, more particularly pages 1.1-1.6) from which the invention is proceeding is based on a direct nebulization of minutest sample quantities of the solids phase by spatial high resolution laser irradiation and transfer of the nebulized sample material into the plasma by an inert carrier gas. Thus, avoiding the usual breaking down of a sample and nebulization of the sample fluid, the samples of solid materials may be directly introduced into the inductively coupled plasma. In this manner, a number of typical analytic problems of the kind occurring when applying conventional techniques, including sample break down and subsequent nebulization, may be avoided. Sample particles nebulized by the laser beam are highly efficiently transferred into the plasma by a transfer system. Almost every kind of solid material sample may be analyzed by the described method of laser vaporation. The samples may be rods, discs, blocks, wire, powder or shavings. Hitherto, metals of highest purity, oxides, supraconductive and geologic materials, glass, ceramics, semiconductor materials, polyethylene and Teflon® have been successfully analyzed. Also, so-called melts, i.e. resolidified solids homogenized by prior melting, have been examined successfully. All of these materials which are suitable for analysis by laser vaporation have in common that at room temperature they are of a solid aggregate state.

Therefore, ice samples whose great importance has been described supra, could not hitherto be analyzed by known analytical methods involving laser vaporation, since at room temperature they are in a liquid state. Moreover, the disadvantages referred to in detail above, especially contamination and low spatial and temporal resolution, will ensue when using a sample of melted ice, so that melting should be avoided if at all possible. The method of preparation referred to above, however, with laser beam assisted ionization and a prior frozen homogenized solution represent only the preparatory step of an analytical method. It is not possible with this method to perform a spatially resolved detection of trace elements in a sample of solid material.

It is thus an object of the invention so to modify an analytical method of detecting spatial distribution patterns of trace elements in a sample of solid materials by direct vaporization by high spatial resolution laser irradiation of the kind mentioned above, that even materials which at room temperature are in a liquid state, but whose melting point is below room temperature, can be examined. This is to be accomplished by simple measures which do not result in a method of higher complexity in terms of apparatus or time or of increased costs. Simple operability by personnel, even with a corresponding device, is to be ensured.

In the method in accordance with the invention, the object is accomplished by the sample of solid material constituted by a natural ice sample or by a frozen biological sample of characteristic solid initial state being disposed in a sample chamber and by cooling, for maintaining the solid initial state of the solids sample during execution of the method, the interior of the sample chamber and the carrier gas stream permeating the sample chamber to temperatures below the melting or solidification point of the solids sample.

In the context of using frozen ice samples as solids samples, the method in accordance with the invention may thus be broadly called a “laser ablation ICP MS”. The phrase “ablation” in this context means the removal of particulate sample material by the bombardment with laser irradiation. However, unlike in the known analytical processes, there is no complete melting. The samples need no longer be thawed and thus come into contact with fewer materials and chemicals. This reduces the ever present danger of contamination in the break-down techniques. Spectral interferences of the kind frequently occurring as a result of break-down reagents and a solvent, are substantially avoided. There is no complex preparation of samples. Sample particles are partially removed from the ice block by laser beam bombardment at a highly spatial and, consequently, temporal resolution of the distribution patterns of trace elements, and are transferred to the plasma flame. The focus of the laser beam constitutes the parameter for the limit of resolution. Depending upon the wavelength of the laser and upon the energy of the impinging laser beam, a high spatial resolution in the range of from 20 μm to 1,000 μm may be attained. The ablation process results in decontamination of the sample and, simultaneously, provides for an in situ control. There exists a high sensitivity of detection in the solid material sample. Aside from ice drill cores, frozen biological samples, for instance, tissue material, may be analyzed in respect of the spatial distribution patterns of their individual components. Microstructures may be examined in a simple manner.

The extremely thin annual layers (in the mm range) in the deeper layers of the ice drill cores created under high pressure and by seasonal deviations in the concentration of elements, may still be recognized by the high spatial resolution and analyzed with respect of the distribution of elements. For purposes of analyzing frozen samples it is, however, necessary that while the method is being practiced the temperature in the sample chamber is maintained below the melting point of the sample in order to prevent thawing of the sample. In accordance with the method of the invention, the interior of the sample chamber as well as the carrier gas stream are cooled for this purpose. In this manner, introduction of heat into the sample chamber is prevented. Precipitations of condensation from the moist carrier gas onto the surface of the sample, which may lead to distorted measurement results, are stopped as well. Water sprays on the optics and melting of the surface of the sample are also prevented. Any and all disturbances by existing water are substantially avoided, since the water is frozen.

A further improvement in maintaining the frozen state and further to influence the advantages as regards the quality of the measurement results can advantageously be achieved by another embodiment of the invention by a cooling temperature in a range up to 30° C. below the melting or solidification point of the solid material sample. This ensures the stability of the frozen samples even at deviations of the cooling temperature. Suitable cooling agents for this cooling range are available. In accordance with a further embodiment of the invention cooling will be accomplished by using ethanol or silicon oil as cooling fluids. Ethanol (spirit) is an alcohol of simple synthesis of small burden on the environment and is often used as a simple solvent. Silicon oil is an environmentally compatible highly viscous light oil. In accordance with a further embodiment of the inventive method, the noble gas argon forms the carrier gas stream. This is a high grade inert gas of high purity and experience gained with it in connection with a known laser nebulization process yielded was excellent. Cooling argon to a temperature range near −30° C. and below may be carried out without any problems, since its own solidification point, as that of all noble gases, is at a very low temperature (Ar: about −190° C.).

In the known analysis methods using laser vaporation the wavelength of the emitted laser light lies in the infrared range of 1,064 nm. For this purpose, a Nd:YAG laser is generally used in an apparatus for executing the method, also known from the above-mentioned handbook (in particular pages 3-5 to 3-10, 6-11 to 6/12 and figure). This is also optimally suitable (in modified form, where required) for use in connection with the laser ablation analysis method in accordance with the invention, for examining frozen samples such as, for example, ice, tissue, serum, small drops or hail stones, in view of the fact that these have a high absorption coefficient in the range of the infrared wavelength. Accordingly, in an advantageous apparatus for practicing the method in accordance with the invention, the laser may be structured as an infrared laser. In accordance with a further embodiment of the invention, the wavelength of the emitted laser light in other samples lies in the optimum absorption range of the solid material sample. In this manner, there will always be an optimum material vaporization.

Experience has shown that the best analytical results are obtained with the known laser vaporization method it at the outset of taking a measurement the flawless operation of the system is checked and optimized, if necessary, with suitable reference materials. The reference materials may be produced in the laboratory or they may be purchased. To establish ice standards for analyzing the elements, commercially available multi-element standards of different concentrations may be frozen in Petri dishes. The thickness of these standards usually is 1 cm. It has been found that at thinner ice samples the laser beam travels through the ice standard and impinges upon the sample support. A simply freezing process in connection with producing the ice standards for the inventive laser ablation analysis method may, however, lead to inhomogeneities and fissures. In accordance with another embodiment of the invention it is thus advantageous to produce standard samples for reference measurements by the repeated spraying of a finely vaporized material solution onto an object support at the selected cooling temperature until a predetermined layer thickness has been reached, or by flash freezing (at about −30° C.) of a material solution of a height of about 1 cm in a Petri dish. In this manner, the production of homogenous material standards free of fissures can be ensured with certainty.

The known apparatus for executing the laser vaporization analysis method is provided with a control and monitoring system with a video monitor including cross-hair generator and a net-powered control computer as well as with a laser arrangement (Nd:YAG laser) with a transfer and focussing optical system. The laser beam is guided by way of the optical system through a cover window into the sample chamber constituted by a sample cell and a sample support table. To align the solid material sample, it is disposed on the table, and the sample cell is then superposed on it and fastened in a pressure-tight manner by rapid closures. The sample table may be moved in every dimension by means of computer-controlled stepper motors.

The high resolution stepper motor control makes possible an exact preselection of the surface of the sample to be analyzed, as well as programming of a raster which is then scanned during laser bombardment. The laser bombardment may arbitrarily be carried out at one point only, along a predetermined line or, in the form of a raster, over a surface. Marking of the point, the line or the surface may take place by clicking a mouse supported by the laser software. The fact of the sample table being controlled completely by the computer makes a very flexible application of the known process possible. For recording the depth distribution of elements the laser is moved to the point of interest of the sample, the necessary focus is adjusted, and the sample is then continuously bombarded (point scan). During the bombardment the laser beam penetrates deeper and deeper into the sample (crater) whereby changing distributions of elements, for instance, may be detected within a sample. In a similar fashion, deep trenches may be formed by continuous bombardment along a line (line scan), and the material may be analyzed. Where the analyte concentrations of a large surface are to be defined, the operation may take place either with a large focus diameter and/or by moving the sample in a predetermined raster under the laser beam during the bombardment.

The structure of the sample chamber is exclusively designed for solid materials of a defined surface for analysis at room temperature. By modifying the system in the context of the invention it is necessary to accommodate frozen samples in a solid aggregate state for analysis by the inventive laser ablation method.

For this purpose, a special apparatus is provided for executing the inventive method of analyzing elements in one or more of the above-described embodiments with the above-described functional elements. It is characterized in particular by the sample chamber consisting of a heat insulating super pure material and being provided with a removable lid as well of a sample dish which may be placed into the interior of the chamber. The heat-conductive super pure metal block with an integrated channel system is arranged beneath the sample dish. The apparatus is further characterized by recirculating cooling device which may be connected by valves and in which is provided a cooling fluid which is connected by heat-insulating pipe connections with the channel system in the metal block as well as with an external cooling box provided in its interior with a heat exchanger which at its warmer side is connected to the carrier gas feed line. The heat-insulating material selected for the sample chamber and for the sample dish may be super pure Teflon® and the heat-conductive super pure material chosen for the metall block may be copper. These materials satisfy the demands placed on them in an optimum manner and ensure a low risk of contamination.

The sample chamber thus constitutes a closed insulation box which may be cooled in a controlled manner. Thus, any desired cooling temperature may be set and maintained in its interior. Frozen samples which have been placed in it will not thaw during analysis. Furthermore, the carrier gas stream is also cooled. Hence, the sample chamber is cooled by the cooling liquid as well as by the carrier gas stream. Appearances of condensation and eliquation processes are largely eliminated. Cooling of the carrier gas takes place by a simple heat exchanger outside of the sample chamber. The heat exchanger may, for instance, be multiply wound cooling coil disposed inside the cooling box which is filled with a cooling liquid.

Furthermore, the laser arrangement in the inventive apparatus may be an adjustable laser which emits light in the range of visible light. With this adjustable laser which may be, for instance, a helium-neon-laser or a laser diode, it is possible in a manner to an optical targeting device, by the image of a visible laser point on the surface of the sample to control its position and to set with high precision. Thus, in situ control of the scanning operation is possible. In the known device, control is possible by the cross hair grid generated on the video monitor only after bombardment with the invisible laser radiation. To avoid repetitions in connection with the embodiments of the apparatus, attention is at this point directed to further explanations relating to the embodiment of the apparatus in the particular section of the specification.

Embodiments of the invention and diagrams relating thereto will for a better understanding be set forth in greater detail on the basis of the schematic figures, in which:

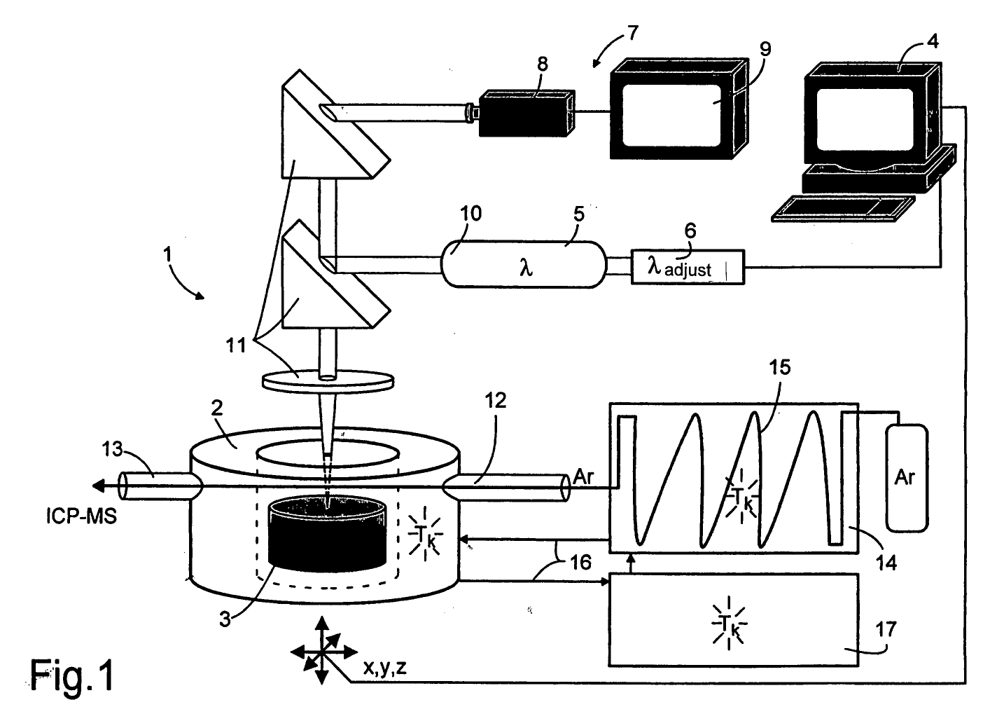

FIG. 1 depicts an apparatus for laser ablation of ice samples with an integrated representation of the process sequence;

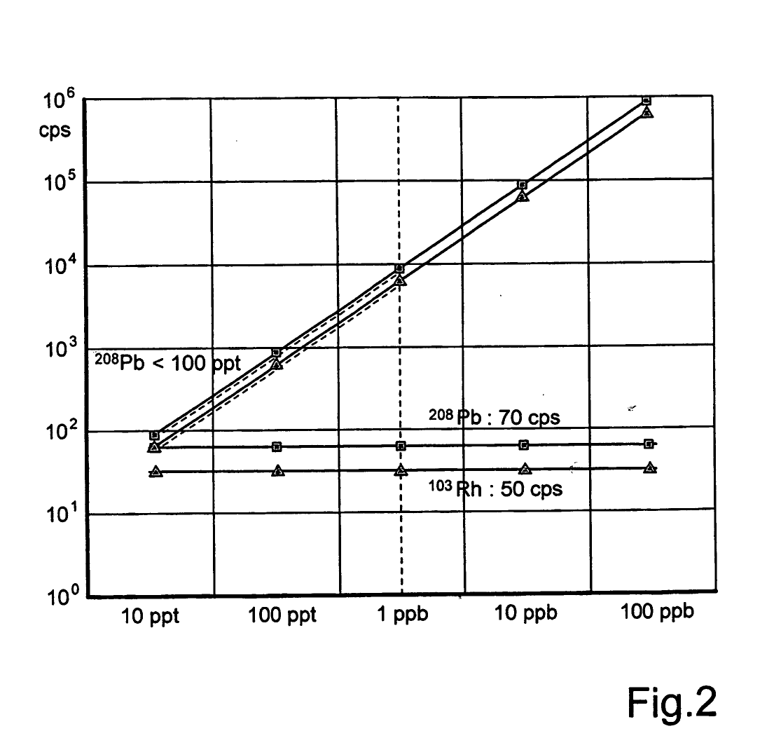

FIG. 2 is a detection diagram for different ice standards;

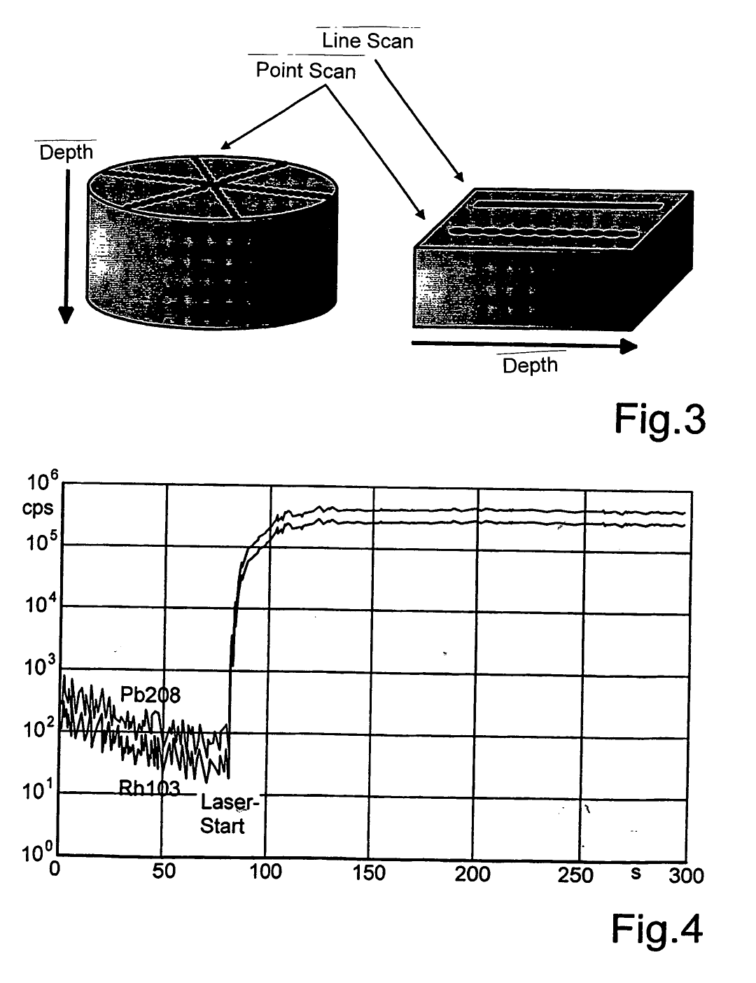

FIG. 3 depicts different ablation patterns;

FIG. 4 depicts a detection diagram for a line scan of an ice sample;

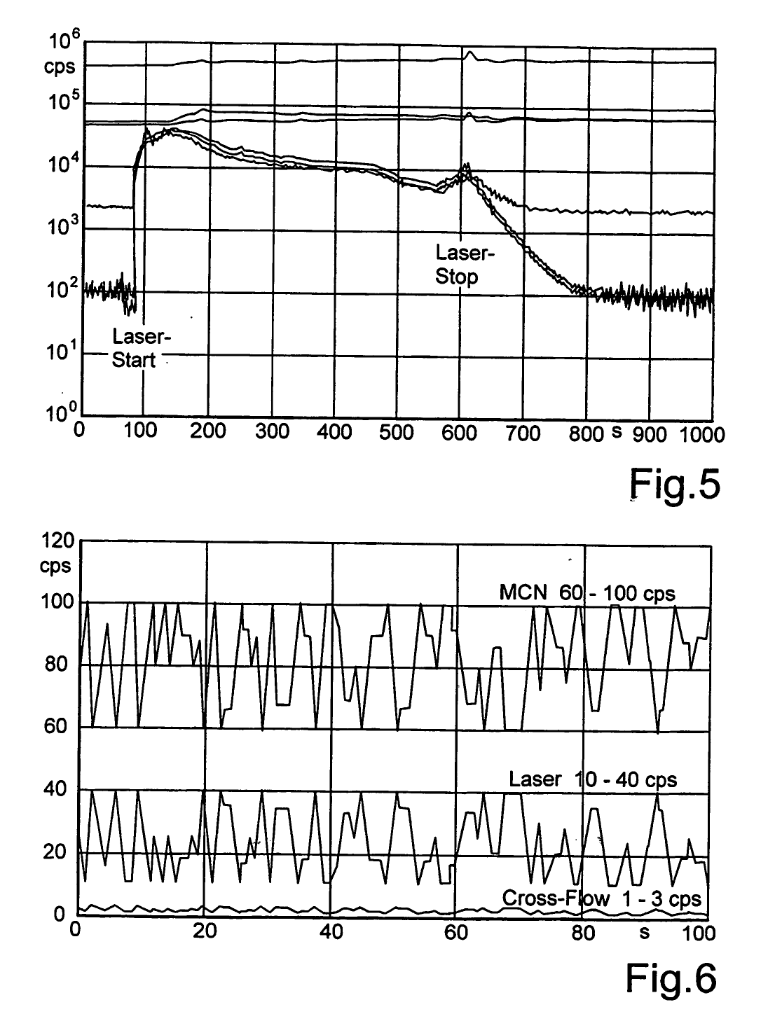

FIG. 5 depicts a detection diagram for a point scan of an ice sample;

FIG. 6 depicts a comparing detection diagram for different insertion systems;

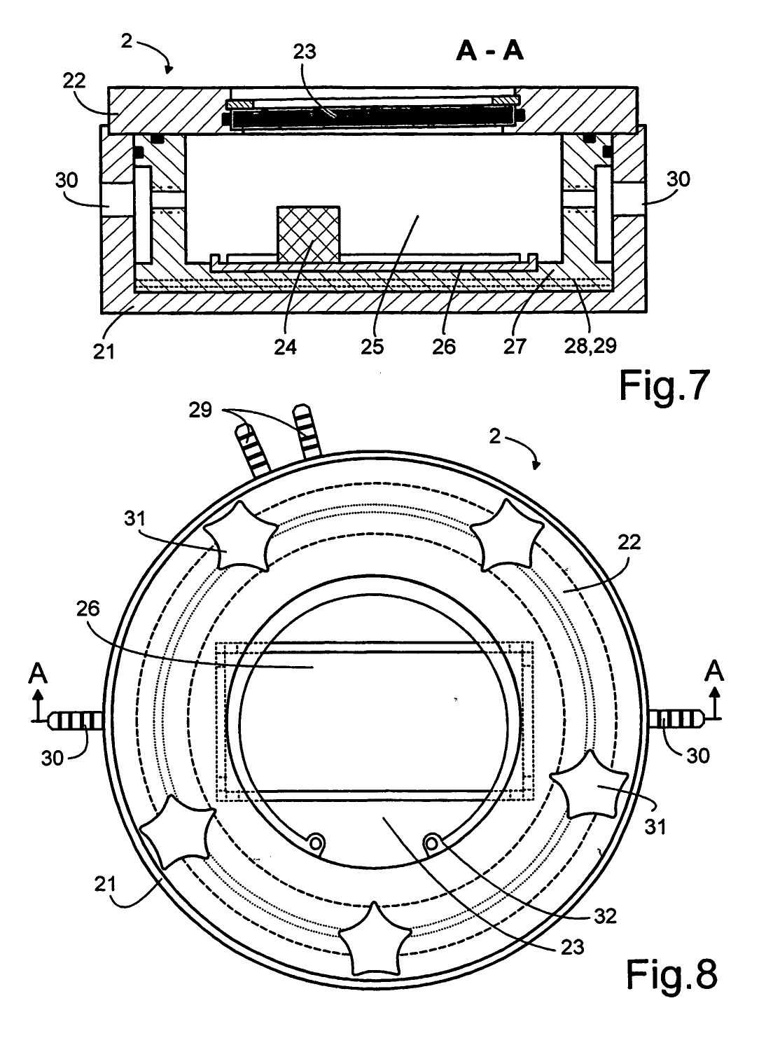

FIG. 7 shows a construction drawing of a sample chamber;

FIG. 8 is a top elevation of a sample chamber similar to FIG. 7; and

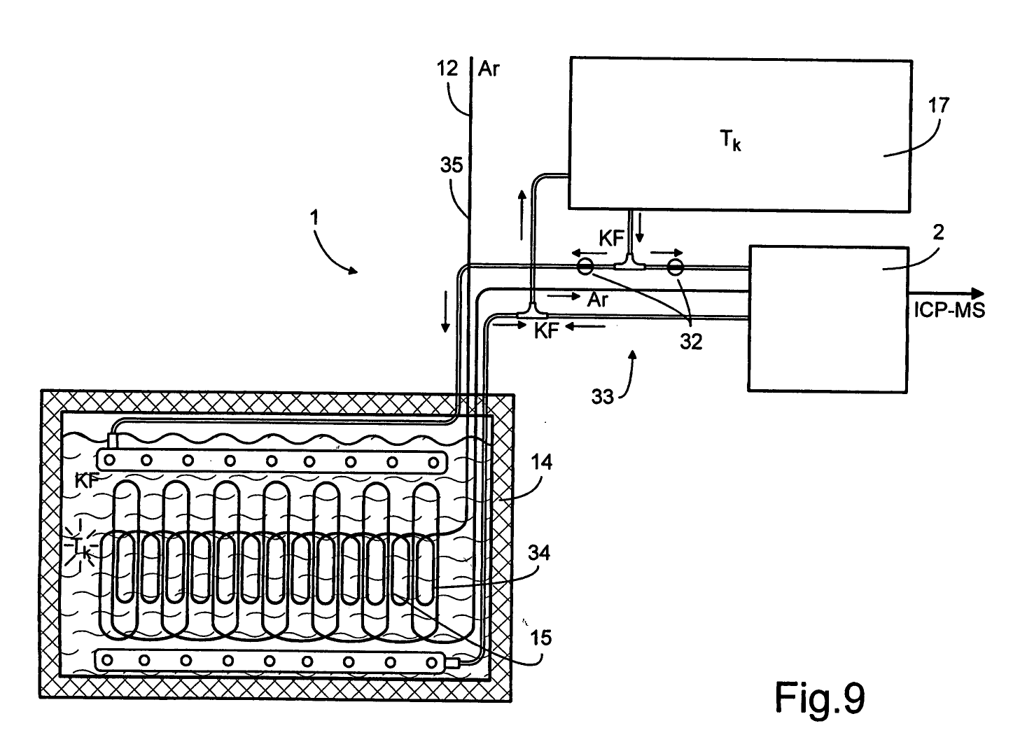

FIG. 9 depicts a recirculation cooling device.

An apparatus 1 for executing the inventive laser-ablation-ICP-MS-method for detecting spatial distribution patterns of trace elements in a solid material sample is schematically shown in FIG. 1. The central element of the apparatus 1 is a sample chamber 2 within which there is disposed a solid material sample 3 in a frozen state which in the example shown is an ice sample. The sample chamber 2 is mounted on a sample table (not shown in detail) which is moveable in all three dimensions x, y and z. The control is exercised by a control computer 4 which also controls a laser device which may be a modification based on the laser sampler 320 of the Perkin-Elmer/Sciex. company. The ice sample 3 is adjusted exactly by means of an adjustable laser 6 which is part of this arrangement and of a monitoring system 7, consisting of a color camera 8 and a video monitor 9, for the protection of operating personnel from the high-energy laser beam. A detection laser 10, also controlled by the control computer 4, generates a laser beam of wavelength A of 1,064 nm which is transmitted by a transfer and focussing optic 11 to the ice sample 3. In the example shown, the detection laser 10 is a powerful Nd:YAG laser (pulse energy of 200 mJ-420 mJ). During the laser bombardment material is ablated from the surface of the ice sample 3 to be examined (optimally, the focus is positioned about 1 mm below the surface) and is transferred by an inert carrier gas stream 12 through a plastic transfer hose 12 into the inductively coupled plasma of a mass spectrometer (e.g. ICP-MS System ELAN 6000 of the Perkin-Elmer/Sciex. Company, plasma power of 1,200 W-1,400 W, dwell time per mass 20 ms-100 ms). In the described embodiment the carrier gas stream 12 is of noble gas argon (1.2 l/min gas flow). The mass spectrometric detection of trace elements in the ablated ice sample takes place in the mass spectrometer.

In the described embodiment the carrier gas stream 12 is cooled in a cooling box 14 by way of a heat exchanger 15 to a temperature Tₖ in the range of −30° C. In a recirculating cooling device 17 (e.g. Unistat 390 W of the Huber Company) the heat absorbed by a cooling liquid 16 (in the selected embodiment it is ethanol C₂H₅OH or silicon oil) filled in the cooling box 14 is removed. In addition, the cooling liquid 16 flows through the sample chamber 2, so that here, too, the prevailing temperature is very low. Both measures—cooling of the sample chamber 2 and of the carrier gas stream 12—ensure that the ice sample 3 does not thaw or eliquate and that no problems occur spraying water.

FIG. 2 depicts a detection diagram of different ice standards for the execution of reference measurements. In the diagram, the counting rate is shown in cps (counts per second) as a measure of the intensity of the element concentration in the ice standard in ppt (parts per trillion or 1 ng/kg) or ppb (parts per billion or 1 μg/kg. Initial examinations of frozen standard solutions have revealed that for a concentration of 100 ppb an intensity of 800,000 cps may be reached for ²⁰⁸Pb and of 600,000 cps for ¹⁰³Rh. By extrapolating the found intensities and assuming a linear curve, a measurable detection limit of less than 100 ppt is possible for ²⁰⁸Pb under the conditions at the time the measurement is taken which can be further optimized. The grounding of these two masses—as a measure for a zero displacement to be taken into consideration—is 70 cps for ²⁰⁸Pb and 50 cps for ¹⁰³Rh. It was possible to verify the extrapolated intensities by experiments.

FIG. 3 depicts different ablation patterns. For instance, in a slice of an ice drill core (shown at the left side of the drawing) an actinoidally applied point scan may be executed in a plane. The measurement results furnish data about the contamination of the margin of the drill core by the drill. In a point scan the laser beam impinges upon a defined point on the surface of the sample and over time it generates a progressively deeper crater. A point or linear scan may, for instance, be performed over the depth in a segment of an ice core (shown at the right of the drawing). In a linear scan a defined line on the surface of the sample is repeatedly scanned and lasered.

FIG. 4 depicts the detection signals (intensity over time) for elements rhodium Rh and lead Pb with a linear scan of an ice standard of 100 ppb. After the laser has been switched on, a stable signal curve may be observed in a line scan. By contrast, FIG. 5 shows the signal curve of a point scan for several elements. It can be seen, that as the depth increases, the focussing of the laser beam in a point scan is no longer correct and that the energy density on the surface of the sample is reduced. As a result, less material is ablated and transferred to the ICP; over time the intensities are reduced. Initial examinations of ice samples yielded a signal stability for ¹⁷OH. It would be possible to apply this signal as a standard signal.

Finally, FIG. 6 depicts a comparison of various background spectra of different sample transfer systems with each other. The aerosol produced by the ablation is usually dry, and in the transfer system (ELAN 6000) applied in accordance with the invention it results in an increased grounding on the mass 220. Presumably, during laser ablation of ice, the carrier gas argon absorbs water from the sample when introduced into the sample chamber. A comparison of the grounding of different sample transfer systems shows that the aerosol generated by laser ablation produces a grounding of 10-40 cps which is below the values of 60-100 cps of a microconcentric nebulizer (MCN 6000, CETAC Company) but higher than those of 1-3 cps of a cross flow nebulizer. The relatively low grounding of the laser aerosol has a positive effect on the detection limits which can be reached. Analogous to a microconcentric nebulizer, a plasma energy of 1,450 W was selected for the laser aerosol.

FIG. 7 depicts a cross-section of a coolable sample chamber 2 of a preferred apparatus for practicing the laser ablation method in accordance with the invention. It consists of a sample housing 21 provided with a removable lid 22. In the selected embodiment both of them are made from heat insulating super pure Teflon®. Centrally of the lid 22 there is arranged an exchangeable quartz cover window 23 through which a laser beam may be directed onto an ice sample 24. The ice sample 24 is positioned in the sample chamber 25 proper on a sample dish 26 which also consists of super pure Teflon®. Since the sample dish 26 has a very thin bottom, its insulating effect relative to a metal block 27 upon which the sample dish 26 is disposed, is negligibly low. For that reason the metal block 27 may be structured as a cooling element made from heat-conductive super pure copper and be provided with an integrated channel system 28. The cooling agent is fed into the channel system 28 by connections 29. The cooled carrier gas is fed into and out of the sample chamber 25 through gas connections 30. The ice sample 24 may thus be positively cooled from below as well as from above.

FIG. 8 is a top elevation of the lid 22 of the sample chamber 2 and its section plane A-A (without the ice sample 24). The two cooling connections 29 are shown adjacent to the gas connections 30. The lid 22 may be thread-connected in a pressure-tight manner with the sample housing 21 by five quick closures 31. Several gaskets, not individually shown, are provided for the pressure seal. In the center of the lid 22 the exchangeable cover window 23 may be seen which is affixed by a safety ring 32. The sample dish 26 may be seen through the cover window 23.

In another embodiment (not shown) the lid is provided with an external thread. The lid may then be simply and quickly threaded into and out of an internal thread in the sample chamber. Additional thread connections and closures are avoided. Cutting threads into the Teflon® material poses no problems and can be carried out with great precision. The threads provide excellent stability as regards guidance.

FIG. 9 schematically depicts the cooling system of the apparatus 1 (see also FIG. 1). It consists of a recirculating cooling device 17 which may be connected with a cooling agent circuit 33 by two valves 32. The preferred cooling liquid 16 (KF) is ethanol or silicon oil. The cooling temperature is about −30° C. All cold pipe connections are heat insulated, for instance as Amaflex® hoses in the embodiment shown. Depending upon the setting of the valves, the cooling liquid KF may be fed from the recirculation cooling device 17 through the sample chamber 2 as well as through the cooling box 14. The cooling box 14 is filled with cooling liquid KF and contains the heat exchanger 15. In the embodiment shown, the heat exchanger consists of a copper coil 34 through which the carrier gas stream 12 of argon Ar in particular, is flowing. The argon Ar is supplied from a feed line 35 and after cooling in the cooling box 14, it flows through the sample chamber 2 and transports ablated particles of the sample to the ICP-MS where the mass spectrometric analysis takes place.

### List of Reference Characters

| 1 | Apparatus |
|---|---|
| 2 | Sample Chamber |
| 3 | Sold Matter Sample |
| 4 | Control Computer |
| 5 | Laser Arrangement |
| 6 | Adjustable Laser |
| 7 | Monitoring System |
| 8 | Color Camera |
| 9 | Video Monitor |
| 10 | Detection Laser |
| 11 | Transfer and Focussing Optics |
| 12 | Inert Carrier Gas Stream |
| 13 | Plastic Transfer Hose |
| 14 | Cooling Box |
| 15 | Heat Exchanger |
| 16 | Cooling Liquid |
| 17 | Recirculation Cooling Device |
| 21 | Sample Chamber |
| 22 | Lid |
| 23 | Cover Window |
| 24 | Ice Sample |
| 25 | Sample Chamber |
| 26 | Sample Dish |
| 27 | Metal Block |
| 28 | Channel System |
| 29 | Cooling Connection |
| 30 | Gas Connection |
| 31 | Quick Closure |
| 32 | Valve |
| 33 | Cooling Agent Circuit |
| 34 | Copper Cooling Coil |
| 35 | Feed Line |
| x, y, z | Dimensions |
| Ar | Argon |
| ICP-MS | Inductively Coupled Plasma Mass Spectrometer System |
| Tₖ | Cooling Temperature |
| KF | Cooling Liquid |

1. Analytical method of detecting spatial trace element distribution patterns in a solid matter sample (3) by computer-assisted spatially resolved ablation of particulate sample material by laser beam bombardment in a sample chamber (2) permeated by a stream (12) of inert carrier gas and subsequent transfer of the separated sample material by the carrier gas stream (12) into an inductively coupled plasma as an ionization source for recording measurements by a mass spectrometer (ICP-MS),
characterized by the fact that
the solid matter sample (3) formed as a natural ice sample (24) or as a frozen biological sample of a characteristic solid initial state is disposed in a sample chamber (2) and that for maintaining the solid initial state of the solid matter sample (3) during execution of the method the interior of the sample chamber (2) and the stream (12) of carrier gas permeating the sample chamber (2) are cooled to temperatures (Tₖ) below the melting or solidification point of the solid matter sample (3).

2. Analytical method according to claim 1,
characterized by the fact that
the cooling temperature (Tₖ) lies in a temperature range up to 30° C. below the melting or solidification point of the solid matter sample (3).

3. Analytical method according to claim 1 or 2,
characterized by the fact that
that cooling is carried out by a suitable cooling liquid (KF, 16), especially ethanol or silicon oil.

4. Analytical method in accordance with at least one of claims 1 to 3,
characterized by the fact that
the stream (12) of carrier gas is constituted by the noble gas argon (Ar).

5. Analytical method in accordance with at least one of claims 1 to 4,
characterized by the fact that
the wavelength (λ) of the emitted laser light lies within the optimum absorption range of the solid matter sample (3), especially in the infrared range.

6. Analytical method in accordance with at least one of claims 1 to 5,
characterized by the fact that
standard samples are produced for carrying out reference measurements by repeated spraying of a finely dispersed material solution on an object support at the selected cooling temperature (Tₖ) until establishment of a predetermined layer thickness or by flash cooling of a material solution of a height of about 1 cm in a Petri dish.

7. Apparatus (1) for practicing the analytical method in accordance with at least one of the preceding claims 1 to 6 for the detection of trace elements in a solid matter sample (3) by a computer-assisted spatially resolved material nebulization by laser beam bombardment with an adjustable laser arrangement (5, 6, 10) with transfer and focussing optics (11) through a cover window (23) into a sample chamber (2) disposed on a three-dimensionally (x, y, z) movable table, and subsequent transfer of the nebulized sample material in a transfer system (13) by a stream (12) of an inert carrier gas (Ar) into an inductively coupled plasma for measurement data recording by a mass spectrometer (ICP-MS) and with a control and monitoring system (4, 8, 9)
characterized by the fact that
the sample chamber (2) consists of a heat-insulating super pure material and is provided with a removable lid (22) as well as with a sample dish (26) positionable in the interior thereof below which there is disposed a heat-conductive super pure metal block (27) with an integrated channel system (28) provided with connections (29) and that there is provided a recirculating cooling device (17) with a cooling liquid (16, KF) connectable by valves (32) and connected by heat-insulating pipe connections to the channel system (28) in the metal block (27) as well as to an external cooling box (14) provided in its interior with a heat exchanger (15) connected at its warmer side to the feed line (35) of the carrier gas.

8. Apparatus for practicing the analytical method according to claim 7,
characterized by the fact that
Teflon® is selected as the heat-insulating super pure material for the sample chamber (2, 21, 22) and copper is selected as the heat-conductive super pure material for the metal block (27).

9. Apparatus for practicing the analytical method according to claim 7 or 8,
characterized by the fact that
the laser (10) of the laser arrangement (5) is structured as an infrared laser, especially in modified form.

10. Apparatus for practicing the analytical method according to at least one of the preceding claims 7 to 9,
characterized by the fact that
as part of the laser arrangement (5) there is provided an adjustable laser (6) which emits laser light in the range of visible wavelengths.
